(19) United States
(12) Patent Application Publication
(10) Pub. No.: US 2015/0138864 A1
(43) Pub. Date: May 21, 2015

(54) MEMORY ARCHITECTURE WITH ALTERNATING SEGMENTS AND MULTIPLE BITLINES

(71) Applicant: LSI CORPORATION, San Jose, CA (US)

(72) Inventors: Donald Albert Evans, Carroll, OH (US); Rasoju Veerabadra Chary, Bangalore (IN); Rajiv Kumar Roy, Bangalore (IN); Rahul Sahu, Bangalore (IN)

(73) Assignee: LSI CORPORATION, San Jose, CA (US)

(21) Appl. No.: 14/086,248

(22) Filed: Nov. 21, 2013

Related U.S. Application Data
(60) Provisional application No. 61/904,739, filed on Nov. 15, 2013.

(51) Int. Cl. G11C 5/06; G11C 11/412; G11C 11/401

(52) U.S. Cl. CPC G11C 5/06; G11C 11/401; G11C 11/412
USPC 365/72

(57) ABSTRACT

Systems and methods presented herein provide a memory system which includes a memory cell array. The memory cell array includes first and second segments with corresponding local bitlines connected to one or more memory cells. The memory cell array also includes first and a second metallization layers. The second metallization layer includes first and second global bitlines. The first metallization layer includes local bitlines. In each of the first segments, local bitlines are connected to one of the first global bitlines. In each of the second segments, local bitlines are connected to one of the second global bitlines.

### CROSS REFERENCE TO RELATED APPLICATIONS

This patent application claims priority to, and thus the benefit of an earlier filing date from, U.S. Provisional Patent Application No. 61/904,739 (filed Nov. 15, 2013), the entire contents of which are hereby incorporated by reference.

### FIELD OF THE INVENTION

The invention generally relates to memory systems, and in particular to a low-power, high-density, and high-speed memory architecture.

### BACKGROUND

Memory devices typically include a memory cell array with a grid of columns and rows. For semiconductor memory architectures such as Static Random Access Memory (SRAM) and Dynamic Random Access Memory (DRAM), rows and columns are referred to as wordlines and bitlines, respectively. Memory cells within the array store bits and are disposed at intersections of wordlines and bitlines. Address decoders select the appropriate row and column to perform a read or write operation on the desired memory cell. A memory architecture with a high density means that the memory cell array contains many rows and columns. Since the bitlines run through the entire range of rows, an increase in the number of rows increases the total capacitance of the bitlines, which not only degrades performance but also increases dynamic power consumption. In a previous solution, the memory array is divided into a number of banks comprising a limited number of rows and a local input/output (I/O) circuit specific to each bank. Unfortunately, the local I/O circuits for each bank increase the area overhead of the memory device.

### SUMMARY

Systems and methods presented herein provide a memory cell array configuration that operates at low power and high speed without an increase in area overhead. In one embodiment, a memory cell array is disclosed. The memory cell array includes first and second segments with corresponding local bitlines connected to one or more memory cells. The memory cell array also includes first and a second metallization layers. The first metallization layer includes local bitlines. The second metallization layer includes first and second global bitlines. In each of the first segments, local bitlines are connected to the first global bitlines and in each of the second segments, local bitlines are connected to the second global bitlines.

The various embodiments disclosed herein may be implemented in a variety of ways as a matter of design choice. For example, some embodiments herein are implemented in hardware whereas other embodiments may include processes that are operable to construct and/or operate the hardware. Other exemplary embodiments are described below.

### BRIEF DESCRIPTION OF THE FIGURES

Some embodiments of the present invention are now described, by way of example only, and with reference to the accompanying drawings. The same reference number represents the same element or the same type of element on all drawings.

FIG. 1 is a block diagram of a memory array architecture 100.

FIG. 2 illustrates a comparison of current in the memory array of FIG. 1 compared with conventional architecture.

FIG. 3 illustrates a comparison of bitline transition in the memory array of FIG. 1 compared with conventional architecture.

### DETAILED DESCRIPTION OF THE FIGURES

The figures and the following description illustrate specific exemplary embodiments of the invention. It will thus be appreciated that those skilled in the art will be able to devise various arrangements that, although not explicitly described or shown herein, embody the principles of the invention and are included within the scope of the invention. Furthermore, any examples described herein are intended to aid in understanding the principles of the invention and are to be construed as being without limitation to such specifically recited examples and conditions. As a result, the invention is not limited to the specific embodiments or examples described below.

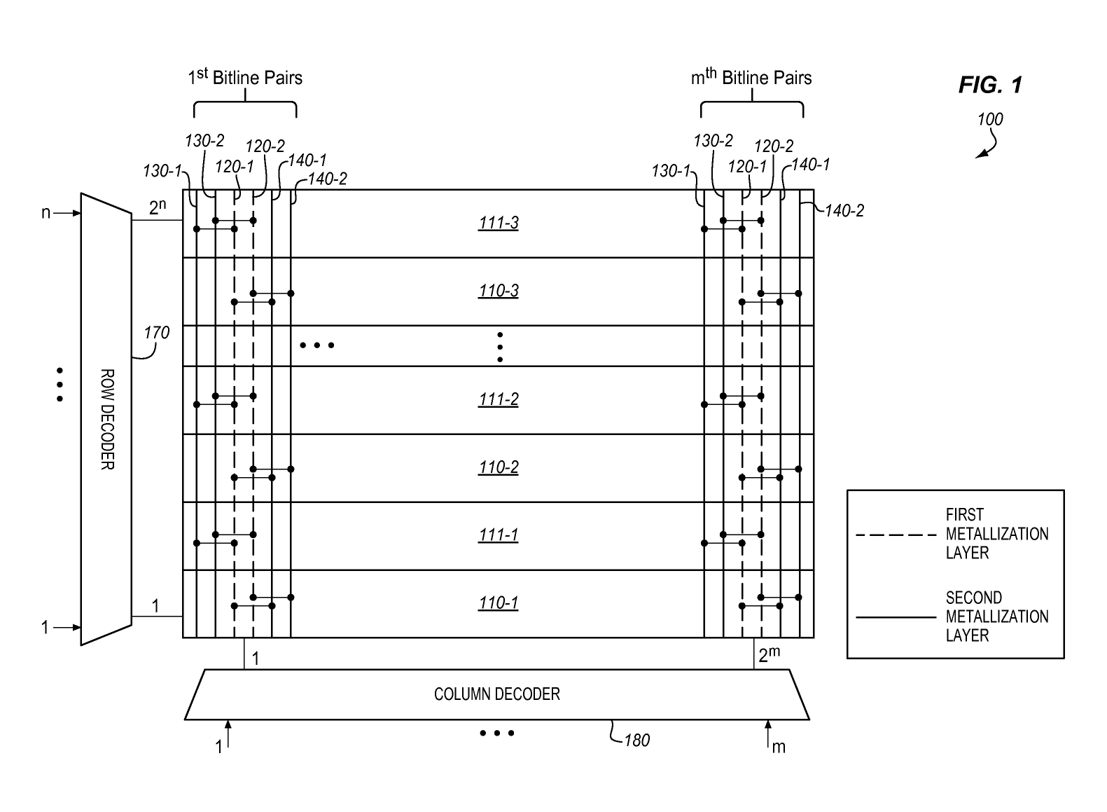

FIG. 1 is a block diagram of a memory array architecture 100. The memory array architecture 100 includes an n bit row address and an m bit column address. The row bits are decoded by a row decoder 170 to select one of the 2ⁿ possible cell array rows. The column bits are decoded by a column decoder 180 to select one of the 2^{m} possible columns. The rows include wordlines and the columns include bitlines. The wordlines and the bitlines form a 2ⁿ2×^{m} grid of memory cells, with a single memory cell located at each intersection point. Data is written into or read from a selected memory cell by applying suitable control signals to a selected word line(s), and/or a selected bit line(s).

The memory array architecture 100 of FIG. 1 may be part of, for example, an SRAM device. As such, the SRAM device may be configured with additional modules not shown to perform input/output (I/O) operations to the memory cells within the memory array architecture 100. For instance, I/O modules and I/O controllers may be used in combination to provide a global I/O to the memory cells of the memory array architecture 100. Additional cores and corresponding global I/O control may be included in the SRAM device.

The memory array architecture 100 includes two metallization layers. When thought of as x, y, and z orthogonal planes, the two metallization layers of the memory array architecture 100 each cover separate horizontal planes in the x and y directions and are spaced over each other in the z direction. Bitlines and their complements run parallel with one another in the y direction in a horizontal plane, and the wordlines run in the x direction of the horizontal plane. Thus, the two metallization layers may be referred to as an upper metallization layer and lower metallization layer.

The memory array architecture 100 is divided into a number of segments 110/111, of which there are two types—even segments 110 and odd segments 111. The even segments 110 and the odd segments 111 may alternate one after another throughout the memory architecture 100 in the y direction, as shown in FIG. 1. In that sense, the segments 110/111 may be thought of as being in consecutive, adjacent pairs throughout the memory array architecture—a first pair of even and odd segments (e.g., 110-1 and 111-1), then a second pair of even and odd segments (e.g., 110-2 and 111-2) and so on. Though just three segment pairs are shown in FIG. 1, virtually any number of even and odd segments throughout the memory array architecture 100 is possible. In one embodiment, the segments 110/111 are included in the lower metallization layer. In an alternative embodiment, the segments 110/111 are included in both the lower metallization layer and the upper metallization layer. In another embodiment, there are additional global bitlines and/or three or more types of segments which alternate and/or repeat in a manner similar to that described above.

Each segment 110/111 is associated with a local bitline 120 that is specific to that segment. The local bitline 120 runs in lower metallization, as indicated by the dashed line in FIG. 1. As is understood in the art, a local bitline 120 can comprise a pair—which may be referred to herein as a true local bitline 120-1 and a complementary local bitline 120-2. Thus, the true local bitline 120-1 and the complementary local bitline 120-2 run in lower metallization and connect to each memory cell in one segment 110/111. It should be noted that the true local bitline 120-1 and the complementary local bitline 120-2 are referred to collectively here for the sake of simplicity and that the terminology is not meant to denote a specific number of bitlines. For instance, for a given column of the memory array architecture 100, there is a separate local bitline 120 in each segment 110/111 instead of just a single local bitline that extends throughout multiple segments 110/111.

In the upper metallization layer, there are two global bitlines—an even global bitline 140 and an odd global bitline 130. Again, it is generally understood that a global bitline can comprise a pair. Thus, the even global bitline 140 may be referred to as a true even global bitline 140-1 and a complementary even global bitline 140-2. Similarly, the odd global bitline 130 may be referred to as a true odd global bitline 130-1 and a complementary odd global bitline 130-2. For a given column, there are the two global bitlines 130/140 running in upper metallization. Thus, each column in the memory array architecture 100 has a plurality of bitline pairs—two pairs of global bitlines in upper metallization (e.g., 130-1, 130-2, 140-1, and 140-2) running across (or above) a range of segments 110/111, and a pair of local bitlines in lower metallization specific to each segment 110/111 (e.g., 120-1 and 120-2).

The local bitline 120 connects to either the even global bitline 140 or the odd global bitline 130 depending on the segment 110/111 in which the local bitline 120 is located. A global I/O toggles one of the two global bitlines 130/140 (i.e., even or odd global bitline) depending on the segment that is being selected (i.e., even or odd segment). To illustrate, in segment 110-1 (i.e., the first even segment), the local bitline 120 connects to the even global bitline 140. In segment 111-1 (i.e., the first odd segment), the local bitline 120 connects to the odd global bitline 130. In order to perform a read or write operation on, for example, a memory cell in the first even segment (i.e., 110-1), a global I/O toggles the even global bitline (i.e., 140) in the column m of that memory cell.

When there are bitline pairs in the memory array architecture 100, the true and complement of a local bitline (i.e., 120-1, 120-2) in an even segment (e.g., 110-1, 110-2, or 110-3) connect to the true and complement, respectively, of the even global bitline (i.e., 140-1, 140-2). And, the true and complement of a local bitline (i.e., 120-1, 120-2) in an odd segment (e.g., 111-1, 111-2, 111-3) connect to the true and complement, respectively, of the odd global bitline (i.e., 130-1, 130-2). This structure may be repeated for each of the m columns of the memory array architecture 100 as shown in FIG. 1.

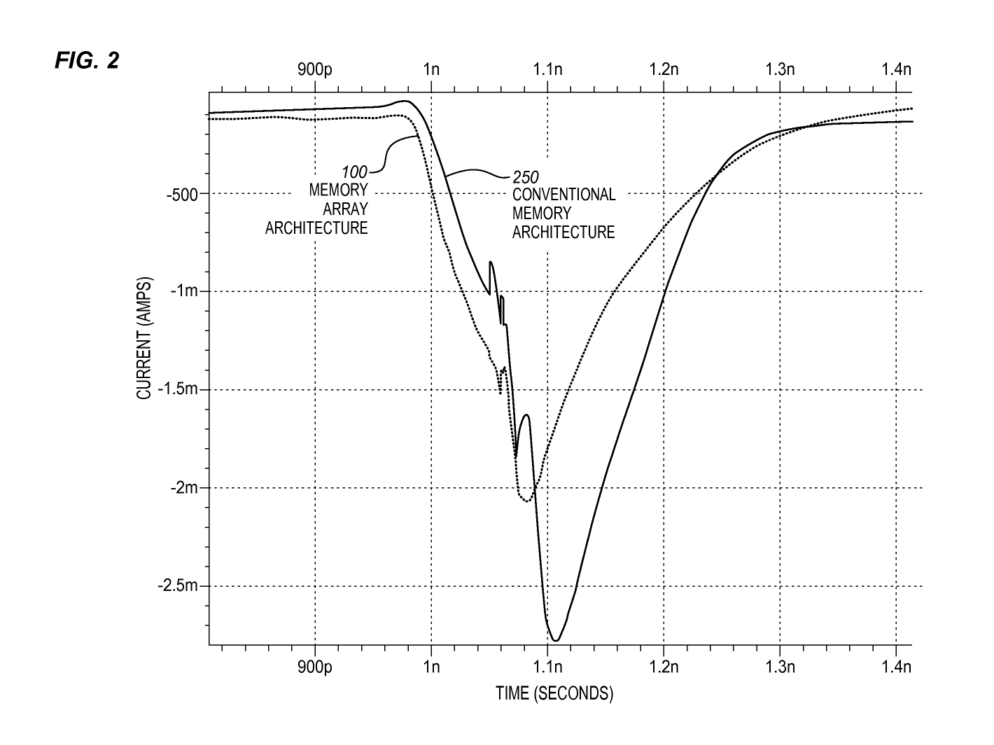

FIG. 2 illustrates a comparison of electrical current in the memory array architecture 100 of FIG. 1 compared with conventional memory architecture 250. Since the memory array architecture 100 is divided evenly, or roughly evenly, into even segments 110 and odd segments 111, the device capacitance on each of the global bitlines 130/140 is reduced by about half. Furthermore, since the local bitlines 120 in lower metallization are connected in parallel with the global bitlines 130/140, the resistance of the bitline is reduced. With reduced resistance and reduced capacitance on the bitlines, the dynamic power consumption within the memory array architecture 100 is reduced.

As seen in FIG. 2, the memory array architecture 100 has reduced write dynamic power consumption. A write operation typically requires more power than a read operation due to the large power dissipation in driving bitlines to full swing. Estimations show that the power dissipated in bitlines represents roughly 70% of SRAM power consumption during a write operation. Thus, the reduced current consumption for driving the bitlines as shown in FIG. 2 results in significant power savings for the SRAM device.

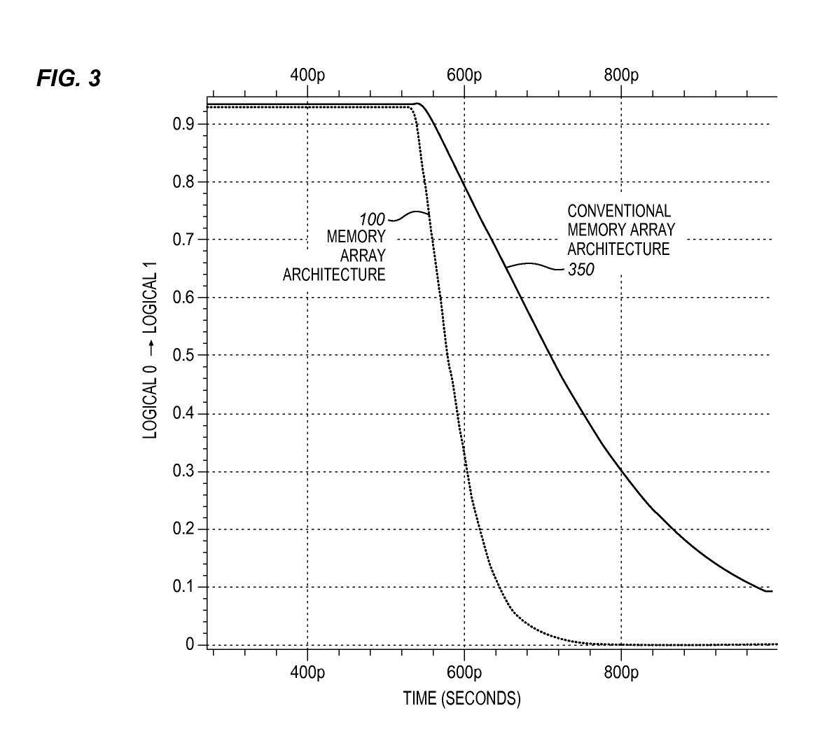

FIG. 3 illustrates a comparison of bitline transition in the memory array architecture 100 of FIG. 1 compared with conventional memory array architecture 350. An additional advantage of the memory array architecture 100 is that the reduced resistance and capacitance also leads to a decrease in the Resistive-Capacitive (RC) delay when charging/discharging the bitlines, thereby decreasing the effective write cycle time. FIG. 3 shows a write bitline being pulled low, from logical 1, or Vdd, to logical 0. With the memory array architecture 100, the bitline is pulled down much faster, resulting in improved speed for the SRAM device. Yet another advantage of the memory array architecture 100 is that it does not require repeated local input/output write circuitry after each segment, reducing the overall area footprint. Rather, a single global I/O is used to address the memory array architecture 100.

It will be appreciated that the terms upper, lower, first, second, even, and odd and the like in the description are used for distinguishing between similar elements and not necessarily for describing a particular orientation or order. In other words, the terms so used are interchangeable under appropriate circumstances and the embodiments of the disclosure herein can operate in orientations and sequences other than that which is described or illustrated herein. Furthermore, while the memory array architecture 100 has been described above with reference to SRAM, embodiments described herein may be useful for other high density memories such as DRAM and other memory architectures. Additionally, the metallization layers may comprise any conductive material such as metal or polysilicon.

In some embodiments, the physical implementation of the memory array architecture 100 can differ from that which is described or illustrated. For example, bitlines and wordlines need not necessarily be orthogonal to one another as shown in FIG. 1. Furthermore, those skilled in the art will understand that additional components not shown or described, such as drivers, latches, decoders, sense amps may be used to access the memory cells in the memory array architecture 100. The figures are simplified schematic views used to discuss the memory array 100 but do not reflect the manner or in any way limit the physical implementation of the memory array 100.

1. A memory cell array comprising:
first and second segments with corresponding local bitlines connected to one or more memory cells; and
first and a second metallization layers, the second metallization layer including first and second global bitlines, and the first metallization layer including local bitlines;
wherein, in each of the first segments, local bitlines are connected to one of the first global bitlines;
wherein, in each of the second segments, local bitlines are connected to one of the second global bitlines; and
wherein the first and the second global bitlines extend in a direction that is across the first and the second segments.

2. The memory cell array of claim 1 further comprising:
global Input/Output circuitry operable to read from and write to a memory cell disposed at the intersection of a row and a column;
wherein, the global Input/Output circuitry toggles a first global bitline in the column to address the memory cell when it is located in one of the first segments; and
wherein, the global Input/Output circuitry toggles a second global bitline in the column to address the memory cell when it is located in one of the second segments.

3. The memory cell array of claim 1 wherein:
each column of the memory cell array includes one of the first global bitlines and one of the second global bitlines.

4. The memory cell array of claim 1 wherein:
first and second segments alternate throughout the memory cell array.

5. The memory cell array of claim 1 wherein:
first and second global bitlines extend through all segments within the memory cell array; and
the local bitlines are specific to each segment within the memory cell array.

6. The memory cell array of claim 1 wherein:
the memory cell array is formed on an Static Random Access Memory device.

7. The memory cell array of claim 1 wherein:
the memory cell array is formed on an Dynamic Random Access Memory device.

8. The memory cell array of claim 1 wherein:
each of the first global bitlines includes a true and complement bitline pair;
each of the second global bitlines includes a true and complement bitline pair; and
each of the local bitlines includes a true and complement bitline pair.

9. A memory device, comprising:
a memory module, comprising:
a second metallization layer comprising first and second pairs of global bitlines; and
a first metallization layer comprising first and second segments of memory cells,
wherein, each segment of memory cells comprises a pair of local bitlines coupled to the memory cells,
wherein, the pair of local bitlines of the first segment is coupled to the first pair of global bitlines, and
wherein, the pair of local bitlines of the second segment is coupled to the second pair of global bitlines, and
wherein, the global bitlines extend in a direction that is across the first and the second segments.

10. The memory device of claim 9, further comprising:
a global Input/Output module coupled to each of the global bitlines to write data to and read data from the memory cells.

11. The memory device of claim 10, wherein:
the global Input/Ouput module is operable to select a column of the memory device corresponding with a desired memory cell, the column connected to the first and second pairs of global bitlines;
wherein, either of the first and second pairs of global bitlines is selected based on whether the desired memory cell is located in one of the first segments or one of the second segments.

12. The memory device of claim 9, wherein:
the first segment and second segments alternate throughout the memory module.

13. The memory device of claim 9, wherein:
the pair of local bitlines in the first segment are coupled in parallel to the first pair of global bitlines; and
the pair of local bitlines in the second segment are coupled in parallel to the second pair of global bitlines.
